(19) United States
(12) Patent Application Publication
(10) Pub. No.: US 2016/0359135 A1
(43) Pub. Date: Dec. 8, 2016

(54) Flexible Electrode Structure, Manufacturing Method Thereof and Flexible Display Substrate

(71) Applicants: Beijing BOE Optoelectronics Technology Co., Ltd., Beijing (CN); BOE Technology Group Co., Ltd., Beijing (CN)

(72) Inventors: Jiaheng Wang, Beijing (CN); Feng Bai, Beijing (CN); Jiuxia Yang, Beijing (CN); Jiantao Liu, Beijing (CN)

(73) Assignees: BOE Technology Group Co., Ltd., Beijing (CN); Beijing BOE Optoelectronics Technology Co., Ltd., Beijing (CN)

(21) Appl. No.: 14/893,887

(22) PCT Filed: May 21, 2015
(86) PCT No.: PCT/CN2015/079493

§ 371 Date: Nov. 24, 2015

(30) Foreign Application Priority Data
Dec. 15, 2014 (CN) 201410778951.1

(51) Int. Cl. H01L 51/52; H01L 51/56; H01L 51/00

(52) U.S. Cl. CPC H01L 51/5215; H01L 51/5234; H01L 51/0097; H01L 51/56; H01L 51/0023; H01L 51/003; H01L 2251/5338; H01L 2251/301

(57) ABSTRACT

A flexible electrode structure, a manufacturing method thereof and a flexible display substrate are disclosed; the flexible electrode structure includes a composite film layer, the composite film layer includes at least one transparent elastic mesh interleaving layer and at least one transparent conductive layer which are alternately stacked with the elastic mesh interleaving layer; the flexible electrode structure can be used as an electrode and applied in the flexible display substrate.

### TECHNICAL FIELD

Embodiments of the present invention relate to a flexible electrode structure, a manufacturing method thereof and a flexible display substrate.

### BACKGROUND

A flexible display technology mainly uses a flexible electronic technology, electronic components and materials of a flexible display medium are disposed on a flexible or bendable substrate, so that the display screen has the characteristics of being bended or curled into any shapes, and has the features of lightness, thinness, portability, etc.

A current flexible display screen uses an electrode formed of a single-layer metal conductive oxide material, typically the above mentioned metal conductive oxide material is an ITO material, and in the operation of bending, folding and extending required for the flexible display, the electrical properties of this material will be affected. Therefore, how to realize the ductility and elasticity operation for the electrode to meet the needs of flexible display, while ensuring the conductive properties of the electrode, is the technical problem necessarily needed to be solved in the related technical field.

### SUMMARY

Embodiments of the present invention provide a flexible electrode structure, a manufacturing method thereof and a flexible display substrate, and the electrode structure which can be achieved has good flexibility and conductive property.

In one aspect, an embodiment of the present invention provides a flexible electrode structure, comprising: at least one transparent elastic mesh interleaving layer and at least one transparent conductive layer which are alternately stacked.

An embodiment of the present invention further provides a flexible display substrate, comprising a flexible base substrate, and a first electrode, a light emitting layer and a second electrode that are sequentially disposed on the flexible base substrate, and the first electrode and/or the second electrode are of the above mentioned flexible electrode structure.

An embodiment of the present invention still further provides a manufacturing method of the above mentioned flexible electrode structure, comprising: forming at least one transparent conductive layer and at least one transparent elastic mesh interleaving layer which are alternately stacked on the carrier substrate; separating the carrier substrate from the at least one transparent conductive layer and the at least one transparent elastic mesh interleaving layer which are alternately stacked.

### BRIEF DESCRIPTION OF THE DRAWINGS

In order to clearly illustrate the technical solution of the embodiments of the invention, the drawings of the embodiments will be briefly described in the following, it is obvious that the described drawings are only related to some embodiments of the invention and thus are not limitative of the invention.

FIG. 1a to FIG. 1d are schematical views of the flexible electrode structure according to embodiments of the invention.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Below in conjunction with the accompany drawings, detailed examples of the specific embodiments of the flexible electrode structure, the manufacturing method thereof and the flexible display substrate provided by the embodiments of the present invention.

In the drawings, the film thickness and the size of each layer do not reflect the real scale of a flexible electrode structure, and the purpose thereof is for only schematic illustration the contents of the present invention.

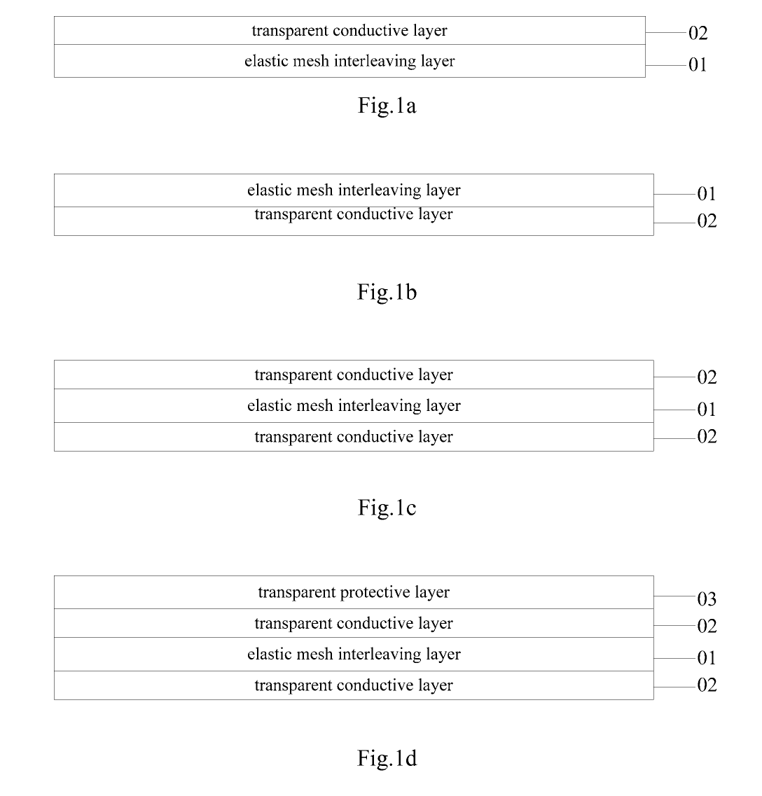

A flexible electrode structure according to an embodiment of the present invention, as shown in FIG. 1a to FIG. 1c, comprises: at least one transparent elastic mesh interleaving layer 01, at least one transparent conductive layer 02 which is disposed alternately stacked with the elastic mesh interleaving layer 01.

It is should be noted that, the foresaid expression “disposed alternately stacked” means the case: in the above mentioned flexible electrode structure provided by the embodiments of the invention, if there are transparent elastic mesh interleaving layers 01 and transparent conductive layers 02, the elastic mesh interleaving layers 01 and the transparent conductive layers 02 are arranged alternately, that is, the materials of adjacent layers are different from each other.

The above mentioned flexible electrode structure according to an embodiment of the present invention, in order to meet the requirements on the capability of bending and stretching operations for a flexible display, comprises a composite film layer, the composite film layer comprises at least one transparent elastic mesh interleaving layer 01 and at least one transparent conductive layer 02 which is disposed alternately stacked with the elastic mesh interleaving layer 01, and the flexible electrode structure can be used as electrode in the flexible display substrate. Because the elastic mesh interleaving layer 01 has a good ductility and elasticity, it can meet the flexibility requirement of the flexible display, and the transparent conductive layer 02, which is disposed alternately stacked with the elastic mesh interleaving layer 01, can meet the conductivity requirement of the electrode in flexible display.

Exemplarily, the sum of the number of the elastic mesh interleaving layers 01 and the number of the transparent conductive layers 02 can be set about two to seven in the above flexible electrode structure provided according to an embodiment of the present invention, and the flexible electrode structure can obtain good conductivity and good ductility. For example as shown in FIG. 1a and FIG. 1b, the number of the elastic mesh interleaving layer 01 and the number of the transparent conductive layer 02 can be one layer respectively, and the transparent conductive layer 02 can be disposed on the upper surface of the elastic mesh interleaving layer 01 as shown in FIG. 1a; or it can be disposed on the lower surface of the elastic mesh interleaving layer 01 as shown in FIG. 1b; or as shown in FIG. 1c, the elastic mesh interleaving layer is disposed as one layer, transparent conductive layers 02 are disposed on the upper surface and the lower surface of the elastic mesh interleaving layer 01 respectively.

Exemplary, because the function of the above mentioned elastic mesh interleaving layer 01 in the flexible electrode structure is to make the electrode structure possess certain flexibility and ductility according to an embodiment of the present invention, the elastic mesh interleaving layer 01 can be formed of a mesh rubber layer for example.

According to the characteristic of the rubber, it can be known that the elastic mesh interleaving layer 01 generally has insulation property, and therefore, if only a transparent conductive layer 02 is provided on either the lower surface or the upper surface of elastic mesh interleaving layer 01, the flexible electrode structure can only achieve unilateral conduction, its electrical conductivity and square resistance is high, and therefore, optionally, the above mentioned flexible electrode structure according to an embodiment of the present invention, as shown in FIG. 1c, can be provided with a plurality of transparent conductive layers 02, to increase conductivity and reduce square resistance.

Moreover, if the uppermost flexible electrode structure, in the above mentioned flexible electrode structure according to an embodiment of the present invention, is a transparent conductive layer 02, due to the influence of water vapor and environmental factors, the property of the transparent conductive layer 02 may be decreased, optionally the above mentioned flexible electrode structure according to the embodiment of the present invention, as shown in FIG. 1d, can further comprise: a transparent protective layer 03 which is disposed on the uppermost transparent conductive layer 02. Exemplary, the transparent resin material can used to form the transparent protective layer 03; of course, other materials may also be used, and the material is not limited herein.

Exemplary, because the elastic mesh interleaving layer 01 in the flexible electrode structure according to an embodiment of the present invention always has the property of insulating, the transparent conductive layer 02 which alternately disposed with the elastic mesh interleaving layer 01 may be in a specific pattern. For example, the pattern can be matched with the pixel pattern in the display panel, to which the flexible electrode structure is applied. Thus, after the production, the flexible electrode structure can be attached to the corresponding display panel directly, and then it can be used as an electrode. Moreover, when in the flexible electrode structure 02 are provided with a plurality of transparent conductive layers 02, generally all the transparent conductive layers 02 are set to have the same pattern, thus in the production the same mask or the same step can used to produce the transparent conductive layers 02 of the same pattern.

Further, the above mentioned flexible electrode structure according to an embodiment of the present invention can use the common transparent conductive oxide material, such as ITO or IZO material, to prepare a transparent conductive layer 02.

Through experiments, the transparent conductive layers 02 formed of ITO are tested; when transparent conductive layers 02 and elastic mesh interleaving layers 01 of different numbers are used to produce the flexible electrode structures in different thicknesses, the conduction performance, ductility and permeability of each sample are tested, and the test results are shown in Table 1.

TABLE 1

| | Thickness | | | |
|---|---|---|---|---|
| | of flexible | | | |
| | electrode | | | |
| Sample | structure | Square resistance | | |
| No. | (nm) | Ω/□ | Ductility (%) | Transmission (%) |
| 1 | 120 | 29 | 119 | 87 |
| 2 | 150 | 25 | 114 | 85 |

Through the tests in experiments, it can be known that, when the common transparent conductive oxide material is used to produce the transparent conductive layers 02, the square resistance of the flexible electrode structure is below 30 Ω/□, the total thickness is between 100 to 200 nm, and on the basis that its conductive property is ensured, its ductility is only less than 20%.

Therefore, in order to realize a good ductility on the basis that the transparent conductive layer 02 meets the requirement of conductivity, a new type of nano-conductive material can be used, that is, the transparent conductive layer 02 is provided as a nano conductive layer. For example, in order to prevent the breakage of a nano conductive layer occurring in the process of extending and avoid affecting its conductive property, nano-metal or nano-metal oxide in rod-like structure can be selected for the material. For example, anyone or a combination of the silver nanowire, gold nanowire, or copper nanowire can be selected as the material of the nanometer conductive layer.

Through experiments, the transparent conductive layers 02 formed of different nano-materials are tested; when nano-material of different particle sizes, and the transparent conductive layers 02 and the elastic mesh interleaving layers 01 in different numbers are used to produce the flexible electrode structures in different thicknesses, test the conducting performance, ductility and permeability of each sample, the test results are shown in Table 2.

TABLE 2

| | | Particle | Thickness | | | |
|---|---|---|---|---|---|---|
| | | size of | of flexible | Square | | |
| | | nano- | electrode | resis- | Duc- | Trans- |
| Sample | Nano- | materials | structure | tance | tility | mittance |
| No. | materials | (nm) | (nm) | Ω/□ | (%) | (%) |
| 1 | silver | 70 | 110 | 15 | 390 | 89 |
| | nanowire | | | | | |
| 2 | silver | 50 | 150 | 10 | 320 | 86 |
| | nanowire | | | | | |
| 3 | silver | 35 | 110 | 8 | 350 | 88 |
| | nanowire | | | | | |
| 4 | silver | 50 | 200 | 5 | 260 | 76 |
| | nanowire | | | | | |
| 5 | gold | 80 | 120 | 16 | 370 | 85 |
| | nanowire | | | | | |
| 6 | gold | 60 | 140 | 14 | 330 | 83 |
| | nanowire | | | | | |
| 7 | gold | 70 | 170 | 11 | 290 | 79 |
| | nanowire | | | | | |
| 8 | gold | 45 | 210 | 7 | 230 | 75 |
| | nanowire | | | | | |
| 9 | copper | 65 | 110 | 17 | 350 | 86 |
| | nanowire | | | | | |
| 10 | copper | 50 | 140 | 11 | 320 | 83 |
| | nanowire | | | | | |
| 11 | copper | 40 | 150 | 9 | 290 | 80 |
| | nanowire | | | | | |
| 12 | copper | 35 | 180 | 6 | 240 | 74 |
| | nanowire | | | | | |

From the test results of Table 2, it can be known that, when nano materials are used to produce the transparent conductive layers 02, compared with the transparent conductive layer 02 made of ITO, the overall ductility of the flexible electrode structures can be greatly improved.

Further, when the silver nanowires with the particle size of 70 nm are used for the transparent conductive layer 02, and the thickness of the produced flexible electrode structure is 110 nm, the comprehensive performance of the flexible electrode structure is better, and the square resistance is lower than 15 Ω/□, the ductility is 390%, and the transmittance is 89%, can meet the needs of the flexible display substrate.

Based on the same inventive concept, a manufacturing method of the above mentioned flexible electrode structure according to an embodiment of the present invention is provided, and comprises the following steps.

S201, forming at least one transparent conductive layer and at least one transparent elastic mesh interleaving layer which are alternately stacked on a carrier substrate;

S202, separating the carrier substrate from the at least one transparent conductive layer and the at least one transparent elastic mesh interleaving layer which are alternately stacked.

Forming of the transparent conductive layer can comprise: forming a transparent conductive material solution on the carrier substrate or the elastic mesh interleaving layer, and solidifying the transparent conductive material solution to obtain the transparent conductive layer.

Forming of the elastic mesh interleaving layer can comprise: forming a pre-polymer mixture material on the carrier substrate or the elastic mesh interleaving layer, and solidifying the pre-polymer mixture material to form the transparent elastic mesh interleaving layer with UV light.

Exemplarily, the carrier substrate used in the above-mentioned step S201 is the support structure for the finally formed flexible electrode; after completion of the production of the flexible electrode structure, the flexible electrode structure needs to be peeled off from the carrier substrate, and therefore, in order to facilitate to peel off the flexible electrode structure to be formed later from the carrier substrate, before the step S201 of “forming at least one transparent conductive layer and at least one transparent elastic mesh interleaving layer which are alternately stacked on the carrier substrate” is performed, the method may further include the following steps: forming the active intermediate layer on the carrier substrate, the adhesion between the active intermediate layer material and the carrier substrate is greater than the adhesion between the active intermediate layer material and the transparent conductive layer or the elastic mesh interleaving layer. For example, if a transparent conductive layer is formed first, the adhesion between the active intermediate layer material and the carrier substrate is required to be greater than the adhesion between the active intermediate layer material and the transparent conductive layer; if the elastic mesh interleaving layer is formed first, the adhesion between the active intermediate layer material and the carrier substrate is required to be greater than the adhesion between the active intermediate layer material and the elastic mesh interleaving layer.

Because before the flexible electrode structure is formed, an active intermediate layer has been produced on the carrier substrate, correspondingly, when the step S202 of “separating the carrier substrate from the at least one transparent conductive layer and the at least one transparent elastic mesh interleaving layer which are alternately stacked” is conducted, for example, it can be achieved in the following ways: in a transfer method or a direct lift-off method, separating the carrier substrate from the at least one transparent conductive layer and the at least one transparent elastic mesh interleaving layer which are alternately stacked.

Exemplarily, for forming the transparent conductive material solution on the carrier substrate in the above mentioned step S201, for example, the transparent conductive material solution can be formed over the entire surface in a coating method; in this case, after the transparent conductive material solution is solidified, the obtained transparent conductive layer is the transparent conductive layer in an entire layer. If in the flexible electrode structure the transparent conductive layers are of the same pattern as the pixels in the flexible display substrate, to which the flexible electrode structure is applied, the transparent conductive layer can be obtained after the transparent conductive layer is formed, so as to form the desired preset pattern.

It can be seen from the above mentioned step S201 that, when forming the transparent conductive material solution in a coating method, the step of the patterning process is needed additionally so as to form the pattern of the transparent conductive layer of a preset pattern, the patterning process is relatively complicate; therefore, in order to simplify the process, when performing the step S201, a print method can be used to form the transparent conductive material solution in the preset pattern directly, so after solidifying the transparent conductive material solution and obtain the transparent conductive layer, the transparent conductive layer in the preset pattern can be obtained.

For example, in the above mentioned step S201, in forming the elastic mesh interleaving layer according to an embodiment of the present invention, the selected pre-polymer mixture material may comprise urethane acrylate pre-polymer, epoxy, initiator, silane coupling agent, and so on.

Based on the same inventive concept, an embodiment of the present invention further provides a flexible display substrate. Because the principle to solve the problem of the flexible display substrate is similar to the above mentioned flexible electrode structure, the flexible display substrate can be referred to the flexible electrode structure, which will not be described here for simplicity.

Exemplarily, the flexible display substrate according to an embodiment of the present invention, comprising: a flexible base substrate, and a first electrode, a light emitting layer and a second electrode that are sequentially disposed on the flexible base substrate, the first electrode and/or the second electrode are the flexible electrode structure(s) provided by the embodiment of the present invention. It should be noted that the flexible display substrate may be modified based on the existing OLED display device, therefore its basic components are roughly the same as the existing OLED display device, which will not be described here for simplicity.

Based on the same inventive concept, an embodiment of the present invention further provides a display device, including the flexible display substrate according to an embodiment of the present invention, the display device can be: a mobile phone, a tablet computer, a television, a monitor, a notebook computer, a digital picture frame, a navigation system and other product or component having a display function. The implement of the display device can refer to the flexible display substrate, which will not be described here for simplicity.

The embodiments of the present invention provide a flexible electrode structure, a manufacturing method thereof and a flexible display substrate, to meet the needs of bending and stretching operations of the flexible display, the flexible electrode structure comprises a composite film layer, the composite film layer comprises at least one transparent elastic mesh interleaving layer and at least one transparent conductive layer which are alternately stacked with the elastic mesh interleaving layer, the flexible electrode structure can be used as an electrode in the flexible display substrate. Because the elastic mesh interleaving layer has good ductility and elasticity and can meet the flexible requirements of flexible display, and the transparent conductive layer which is disposed alternately stacked with the elastic mesh interleaving layer can meet the conductivity requirement of the electrode in a flexible display.

Obviously, those skilled in the art may make various modifications and variations to the present invention but not departing from the spirit and scope of the invention. Thus, if these modifications and variations of the present invention belong to the scope of the claims of the invention and their equivalents technology, the present invention is also intend to include these modifications and variations.

The present application claims the priority of the Chinese Patent Application No. 201410778951.1 filed on Dec. 15, 2014, which is incorporated herein by reference as part of the disclosure of the present application.

1. A flexible electrode structure comprising: at least one transparent elastic mesh interleaving layer and at least one transparent conductive layer which are alternately stacked.

2. The flexible electrode structure claimed as claim 1, wherein a sum of a number of the at least one elastic mesh interleaving layer and a number of the a least one transparent conductive layer is two to seven.

3. The flexible electrode structure claimed as claim 1, wherein the elastic mesh interleaving layer is of one layer, and the transparent conductive layer is disposed on the upper surface and/or the lower surface of the elastic mesh interleaving layer.

4. The flexible electrode structure claimed as claim 1, wherein the flexible electrode structure comprises a plurality of transparent conductive layers, and each transparent conductive layer has a same pattern.

5. The flexible electrode structure claimed as claim 1, further comprising: a transparent protective layer which is disposed on the transparent conductive layer in an uppermost layer of the at least one elastic mesh interleaving layer and the at least one transparent conductive layer.

6. The flexible electrode structure claimed as claim 1, wherein the transparent conductive layer is a nanometer conductive layer.

7. The flexible electrode structure claimed as claim 6, wherein a material of the nanometer conductive layer is nano-metal or nano-metal oxide of a rod-like structure.

8. The flexible electrode structure claimed as claim 7, wherein the material of the nanometer conductive layer is anyone or a combination of silver nanowire, gold nanowire or copper nanowire.

9. The flexible electrode structure claimed as claim 1, wherein the elastic mesh interleaving layer is a mesh rubber layer.

10. A flexible display substrate comprising a flexible base substrate, and a first electrode, a light emitting layer and a second electrode that are sequentially disposed on the flexible base substrate, wherein, the first electrode and/or the second electrode is of the flexible electrode structure claimed as claim 1.

11. A manufacturing method of flexible electrode structure, comprising:
forming at least one transparent conductive layer and at least one transparent elastic mesh interleaving layer which are alternately stacked on a carrier substrate; and
separating the carrier substrate from the at least one transparent conductive layer and the at least one transparent elastic mesh interleaving layer which are alternately stacked.

12. The manufacturing method claimed as claim 11, wherein forming the transparent conductive layer comprises: forming transparent conductive material solution on the carrier substrate or the elastic mesh interleaving layer, solidifying the transparent conductive material solution to obtain the transparent conductive layer.

13. The manufacturing method claimed as claim 11, wherein forming of the elastic mesh interleaving layer comprises:
forming a pre-polymer mixture material on the carrier substrate or the transparent conductive layer, and
solidifying the pre-polymer mixture material with UV light to form the transparent elastic mesh interleaving layer.

14. The manufacturing method claimed as claim 11, wherein forming of the transparent conductive material solution comprises: forming the transparent conductive material solution over an entire surface in a coating method; and
after obtaining the transparent conductive layer, the method further comprises:
patterning the transparent conductive layer to form a preset pattern.

15. The manufacturing method claimed as claim 11, wherein forming of the transparent conductive material solution comprises:
forming the transparent conductive layer in a preset pattern in a printing method.

16. The manufacturing method claimed as claim 11, wherein the pre-polymer mixture material comprises: urethane acrylate prepolymer, epoxy, initiator, and silane coupling agent.

17. The manufacturing method claimed as claim 11, before forming at least one transparent conductive layer and at least one transparent elastic mesh interleaving layer which are alternately stacked on the carrier substrate, further comprising:
forming an active intermediate layer on the carrier substrate, wherein adhesion between the active intermediate layer material and the carrier substrate is greater than adhesion between the active intermediate layer material and the transparent conductive layer or the elastic mesh interleaving layer.

18. The manufacturing method claimed as claim 17, wherein separating of the carrier substrate from the at least one transparent conductive layer and the at least one transparent elastic mesh interleaving layer which are alternately stacked, comprises:
in a transfer method or a direct lift-off method, separating the carrier substrate from the at least one transparent conductive layer and the at least one layer of transparent elastic mesh interleaving layer which are alternately stacked.

19. The manufacturing method claimed as claim 12, wherein forming of the elastic mesh interleaving layer comprises:
forming a pre-polymer mixture material on the carrier substrate or the transparent conductive layer, and
solidifying the pre-polymer mixture material with UV light to form the transparent elastic mesh interleaving layer.
